(19) United States
(12) Patent Application Publication
(10) Pub. No.: US 2003/0025167 A1
(43) Pub. Date: Feb. 6, 2003

(54) Activating in-situ doped gate on high dielectric constant materials

(75) Inventors: Heemyong Park, LaGrangeville, NY (US); William H. Ma, Fishkill, NY (US); Fariborz Assaderaghi, San Diego, CA (US)

Correspondence Address: INTERNATIONAL BUSINESS MACHINES CORPORATION, DEPT. 18G, BLDG. 300-482, 2070 ROUTE 52, HOPEWELL JUNCTION, NY, 12533, US

(73) Assignee: International Business Machines Corporation, Armonk, NY

(21) Appl. No.: 09/919,316

(22) Filed: Jul. 31, 2001

(51) Int. Cl. H01L 29/76

(52) U.S. Cl. 257/408

(57) ABSTRACT

A semiconductor transistor on a substrate, the transistor comprising activated source, drain and gate regions, and a channel region between the source and drain region, the channel underlying the gate region and wherein at least a portion of the gate region comprises a thermally non-degraded high dielectric constant material.

### FIELD OF THE INVENTION

This invention is directed to the structure and formation of transistors used in the semiconductor industry. More particularly, the present invention is directed to a high dielectric constant transistor structure having a doped gate.

### BACKGROUND OF THE INVENTION

Semiconductor technologies have consistently decreased in size and increased in functionality with each generation. As the trend continues, it has been necessary to reduce the size of the transistors in the semiconductor as one of the ways to decrease the size of the chips. As the size of transistors has decreased different changes in materials and processing have been explored. One change that would increase the functionality of the transistors in general and CMOS transistors specifically would be to change the materials forming one or all parts of the transistors.

Difficulties exist when contemplating the change of materials in a CMOS transistor. Since the use of silicon dioxide as the gate dielectric is widespread and it would be difficult to introduce a material that made the use of silicon difficult or add degrees of difficulty (or impracticality) to other steps in transistor processing. One advance that has been proposed is the use of high dielectric constant materials as the material used for the gate region of a semiconductor transistor.

The term high dielectric constant material is usually meant to denote materials with a range of dielectric constants that are measured against the dielectric constant of silicon dioxide. For purposes of this invention, high dielectric constant materials are generally materials with a dielectric constant greater than silicon dioxide. Examples of high dielectric constant materials include, but are not limited to metal oxides like Al₂O₃, HfO₂, ZrO₂, CeO₂, Y₂O₃, Ta₂O₅ TiO₂, SrTiO₃ (STO), BaSrTiO₃ (BST) and combinations thereof. For any given thickness as compared to silicon dioxide, high dielectric constant materials reduce tunneling leakage current and improve the reliability. There are disadvantages to using high dielectric constant materials. One of the most significant disadvantages is that high dielectric constant materials are not as thermally stable as their lower dielectric constant counterparts. For example, high dielectric constant materials may form silicides or low dielectric constant interfacial layers when directly contacted with silicon. Different high dielectric constant materials will react in varying degrees. Given this limitation it has been difficult to integrate high dielectric constant materials in current processing schemes typically anneal at temperatures that would cause thermal degradation in high dielectric constant materials. When high dielectric materials are thermally degraded the benefits of using a high dielectric material are significantly diminished.

Thus there remains a need for a method and structure for a semiconductor transistor which incorporates high dielectric constant materials into functional transistor designs and processing.

### SUMMARY OF THE INVENTION

It is therefore an object of the present invention to provide a method for incorporating high dielectric materials into an annealed, doped transistor structure.

It is a further object to provide a method for incorporating high dielectric constant material into the gate region of a doped semiconductor transistor.

It is another object of the instant invention to provide a method for shielding high dielectric constant materials from the thermal effects of annealing.

In accordance with the above listed objects, we provide a semiconductor transistor, comprising:

A semiconductor transistor on a substrate, the transistor comprising activated source, drain and gate regions, and a channel region between the source and drain region, the channel underlying the gate region and wherein at least a portion of the gate region comprises a thermally non-degraded high dielectric constant material.

### BRIEF DESCRIPTION OF THE DRAWINGS

The invention is best understood from the following detailed description when read in connection with the accompanying drawing. It is emphasized that, according to common practice, the various features of the drawing are not to scale. One the contrary, the dimensions of the various features are arbitrarily expanded or reduced for clarity. Included in the drawing are the following figures:

FIGS. 1-6 are cross-sectional views showing the process sequence used to form a structure according to the instant invention. More specifically, FIG. 1 shows a MOSFET structure with a dummy gate.

FIG. 2 shows insulator deposition.

FIG. 3 shows the removal of the dummy gate.

FIG. 4 shows the deposition of the high dielectric constant material

FIG. 5 shows the planarized material deposited as the gate.

FIG. 6 shows the laser absorption layer.

FIG. 7 shows a semiconductor structure according to the method of the instant invention.

### DETAILED DESCRIPTION OF THE INVENTION

The speed for future generations of transistor design may be limited by the materials that are used to fabricate them. Current lower dielectric constant materials limit the speed at which electrons can flow through the tunnel and between the source/drain and gate. As increased speed and reliability demands create the need for faster transistors, transistor designers have contemplated different methods of increasing the speed and efficiency of transistors in general and CMOS transistors specifically.

One way to increase the speed and reliability of CMOS transistors is to change and/or modify the material used to form the different layers of materials, including the gate insulator material. Where it is advantageous to have higher speed CMOS transistor, use of a high dielectric constant material (high k) can give the increased performance. High k dielectric materials generally lead to higher gate capacitance and lower gate leakage. Examples of high k materials include, but are not limited to hafnium oxide, aluminum oxide and hafnium silicates. One of the limitations that the instant inventors encountered when using high dielectric constant material is that high dielectric constant materials are more sensitive to heat degradation than lower dielectric constant materials.

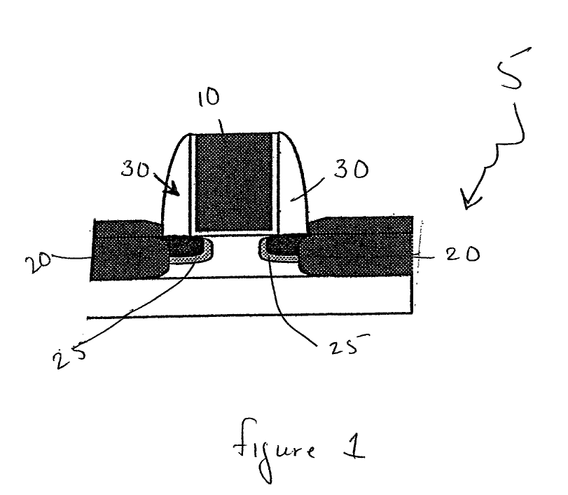

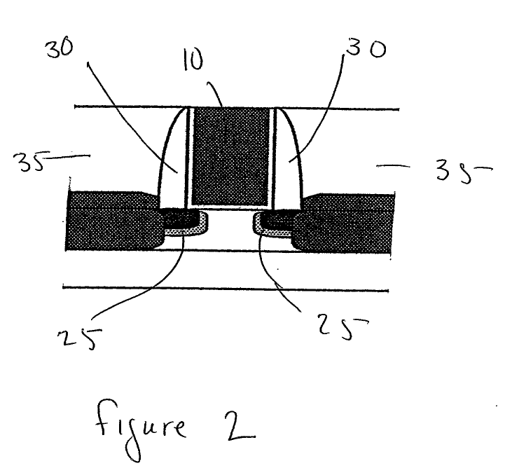

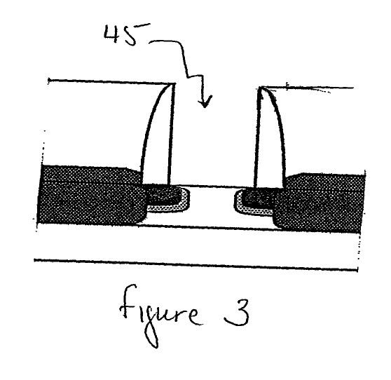

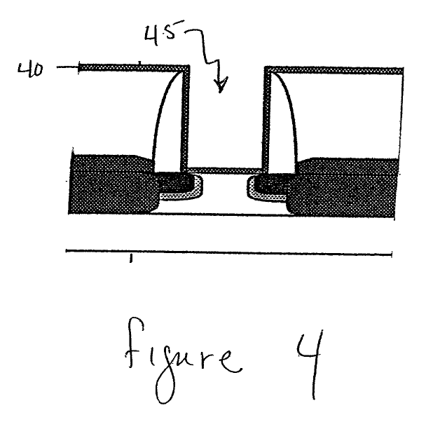

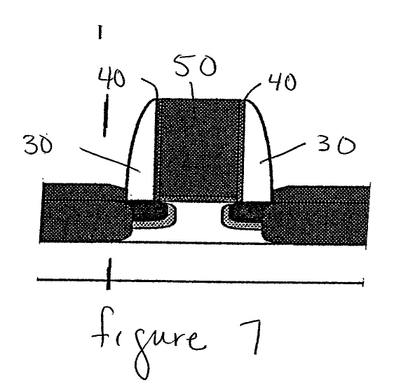

The instant invention is drawn to a transistor design that incorporates a high dielectric constant material. The steps of which are shown in FIGS. 1-6. The final structure is given in FIG. 7. Turning to the figures in general and FIG. 1 specifically, FIG. 1 shows a conventional MOSFET, 5, with a dummy gate, 10, and fully activated source/drain, 20, and extension doping, 25. The conventional MOSFET may be formed by any means known in the art. The dummy gate may be composed of any material. Preferably, the dummy gate would be composed of a material with properties such that the permanent spacers, 30, would not be effected by an etch. As shown in FIG. 2 an insulator, 35, would be deposited and planarized. Preferably, the insulator would be a polysilicon and more preferably TEOS (tetra ethyl ortho silicate). Also preferably the planarization would be by chemical/mechanical polishing and the dummy gate would be the etch stop. The dummy gate, 10, would then be etched, preferably leaving only the permanent spacers, 30, as shown in FIG. 4. Preferably, the etch would be either an anisotropic etch or a wet etch with high selectivity. More preferably, the etch would also remove any sidewall reoxidation. Next, the high dielectric constant material, 40, is deposited as shown in FIG. 4 by any means known in the art. Preferably, the thickness of the high dielectric constant material would be at least about 15 angstroms and at most about 60 angstroms. Preferably, an interfacial layer would be deposited before the high dielectric constant material. Optionally, low temperature densification may occur after the deposition of the high dielectric constant material. After the high dielectric constant material is deposited, a layer of lower dielectric constant material is deposited such that at least the area etched dummy gate area, 45, is substantially filled. The material in the gate region must eventually be doped. There are numerous ways to achieve the desirable doping of the just deposited material. The doping should occur such that the integrity of the high dielectric material is not compromised. Preferably the annealing would take place in stages with the first stage occurring after with deposition of the material. The material can be deposited as a heavily doped amorphous silicon or as a partially doped polysilicon. Alternately, the material can be deposited as an undoped polysilicon and doping can occur as an implant.

The annealing done in the first stage is not sufficient to activate the polysilicon without additional anneals. As stated infra, the temperature needed to accomplish an anneal in conventional processes would exceed the time that a high dielectric material could remain in the annealing temperature range and maintain material integrity. Specifically, the high dielectric material could recrystallize and there could be a reduction in the desirable dielectic properties of the high delectric constant material. Preferably the polysilicon would be deposited using a rapid thermal CVD (RTCVD) process. The temperature during the RTCVD would be about 650-750° C. The doping achieved in the first stage is usually not sufficient to activate the polysilicon without additional (stage 2) anneals. The stage 2 anneals are needed to cause activation and poly-crystallization.

In the prior art traditional stage 2 anneals would take place next at temperatures where high dielectric material integrity is improbable. For example, a typical prior art stage 2 anneal would be accomplished at a temperature of above 1000C. for more than several seconds. A thermal cycle of that length at that temperature would cause the high dielectric constant material to recrystallize and degrade.

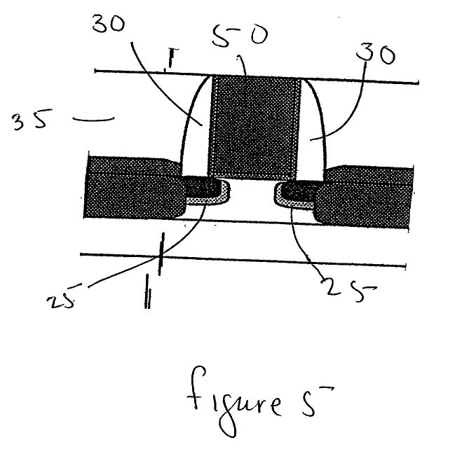

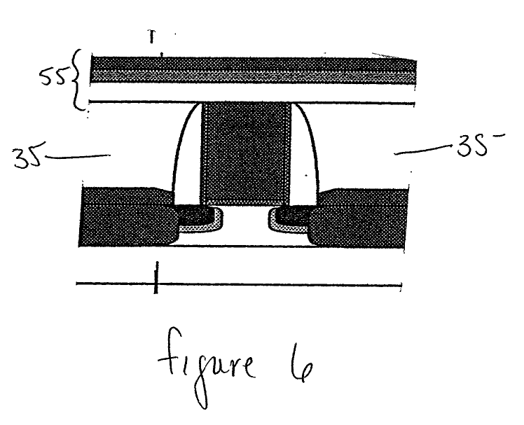

In the first embodiment of the instant invention the amorphous silicon/polysilicon material, 50, deposited would be planarized, as shown in FIG. 5. Preferably, the planarization would involve a chemical mechanical polishing and the insulator, 35, would act as an etch stop. To protect the underlying high dielectric constant material from the stage 2 annealing step that still needs to be done, a laser absorption layer, is deposited. The laser absorption layer needs to be able to absorb heat such that the instantaneous peak temperature at the gate dielectric surface is sufficiently diminished as to not cause thermal degradation. Preferably, the laser absorption layer would be a three layer structure comprised of conductive layers underlying a insulating layer, as shown in FIG. 6. More preferably, the laser absorption layer would comprise a first sublayer of TEOS, a second sublayer of TiN and a third sublayer of Ti. Most preferably, the sublayer of TEOS would be about 150 Å-250 Å, the sublayer of TiN would be about 50 Å-400 Å and the sublayer of Ti would be about 50 Å-200 Å.

A non-melting laser preanneal is then performed. As opposed to a melting laser anneals, the non-melting laser anneal with reduced power does not melt the high dielectric constant material and as a result the peak temperature is lower and the gate region is not adversely affected thermally. It is critical that the laser pre-anneal be accomplished at a temperature and for a duration that does not cause high dielectric constant material thermal degradation. For example, a standard non-melting laser anneal at 1100C. for 30 nanoseconds would accomplish the benefits of the non-melting laser anneal. The quick heating from the laser initiates the necessary polycrystallization of the deposited amorphous/poly layer and activates the dopants in the layer (if present). Due to the ultra-short duration of the anneal and due to the fact that the relatively thick (how thick) polysilicon works as a thermal buffer, the high dielectric constant material acts as a thermal buffer. Preferably, the duration of the non-melting laser anneal would be sufficient to achieve the solid solubility limit for dopant activity in the amorphous/poly layer. Also preferably, the non-melting laser anneal would be directed to substantially only the amorphous/poly gate region, 50. To complete the step 2 anneal a rapid thermal anneal (RTA) would be done at a temperature below the melting temperature of the high dielectric constant material. Preferably the RTA would be accomplished at less than about 1000C. Once the RTA is accomplished the insulating layer can be removed. Preferably the removal would be a wet etch using a high selectivity chemistry. More preferably, the wet etch chemistry would include HF. In a preferred embodiment a silicidation would occur after the removal of the insulating layer. It is difficult to identify the exact temperature and duration that would cause thermal degradation for an individual high dielectric constant material because the threshold for recrystallization of the material and the onset of leakage increase are affected by the material surrounding the high dielectric constant material. For example, the temperature/duration could be different if the material deposited in the gate region after the high dielectric constant materials were a metal or a polysilicon. Additionally, the presence of sidewall spacers might also act as a temperature buffer and affect the temperature/duration value for a given high dielectric constant material.

In an alternate embodiment, the step 2 anneal would be a non laser anneal and the non-melting pre-laser anneal would not have to be accomplished. In that embodiment, the laser absorption layer would not have to be deposited. All other processing steps remain the same, as would the final structure as shown in FIG. 7.

While the invention has been described in terms of specific embodiments, it is evident in view of the foregoing description that numerous alternatives, modifications and variations will be apparent to those skilled in the art. Thus, the invention is intended to encompass all such alternatives, modifications and variations which fall within the scope an spirit of the invention and the appended claims.

What is claimed:

1. A semiconductor transistor, comprising:
A semiconductor transistor on a substrate, the transistor comprising activated source, drain and gate regions, and a channel region between the source and drain region, the channel underlying the gate region and wherein at least a portion of the gate region comprises a thermally non-degraded high dielectric constant material.

2. The transistor of claim 1 further comprising sidewall spacers, the spacers on the left and right sides of the gate.

3. The transistor of claim 2 wherein the gate region comprises a layer of a thermally non-degraded high dielectric material deposited on the spacers, the gate region filled with a lower dielectric material, the lower dielectric constant material in contact with the high dielectric constant material.

4. The transistor of claim 1 wherein the high dielectric material is selected from the group consisting of Al₂O₃, HfO₂, ZrO₂, CeO₂, Y₂O₃, Ta₂O₅ TiO₂, SrTiO₃ (STO), BaSrTiO₃ (BST) and combinations thereof.

5. The transistor of claim 3 wherein the high dielectric material is selected from the group consisting of Al₂O₃ HfO₂, ZrO₂, CeO₂, Y₂O₃, Ta₂O₅, TiO₂, SrTiO₃ (STO), BaSrTiO₃ (BST) and combinations thereof.

6. The transistor of claim 5 wherein the lower dielectric constant material comprises a metal.

7. The transistor of claim 5 wherein the lower dielectric constant material comprises a polysilicon.

8. The transistor of claim 2 wherein the sidewalls spacers comprise a nitrogen containing compound.

9. The transistor of claim 1 wherein the substrate is selected from the group consisting of silicon and silicon on insulator.

10. A method of forming a semiconductor transistor having a thermally non-degraded high dielectric constant gate region, the method comprising the steps of:
a) providing a semiconductor transistor on a substrate, the transistor having activated source and drain regions, sidewall spacers and a gate region, the gate region comprising high dielectric constant material and lower dielectric constant material;
b) activating the gate region, wherein the high dielectric constant materials is not thermally degraded.

11. The method of claim 10 wherein the activating comprises the steps of:
a) depositing an insulating layer;
b) depositing a laser absorption layer;
c) annealing the gate region such that the high dielectric constant material is not thermally degraded;
d) removing the laser absorption layer.

12. The method of claim 11 wherein the insulating layer is planar with the transistor.

13. The method of claim 11 wherein the laser absorption layer comprises at least two layers, the first layer an insulating layer and the second layer a conductive layer.

14. The method of claim 13 wherein the second layer, a conductive layer comprises at least about two layers.

15. The method of claim 14 wherein the conductive layer comprises a member selected from the group consisting of tantalum, tantalum nitride, titanium, titanium nitride and combinations thereof.

16. The method of claim 11 wherein the annealing comprises the following steps:
a) a laser anneal; and
b) a rapid thermal anneal.

17. The method of claim 16 wherein the laser anneal is a non-melting laser anneal.

18. A method of forming a semiconductor transistor having a thermally non-degradable high dielectric constant gate region, the method comprising the steps of:
a) providing a semiconductor transistor on a substrate, the transistor having activated source and drain regions, sidewall spacers and a gate region;
b) depositing an insulating layer;
c) planarizing the insulating layer such that the gate region is exposed;
d) selectively removing the material forming the gate region;
e) depositing a first dielectric material, the first material comprising a high dielectric material;
f) depositing a second dielectric material, the second material comprising a lower dielectric constant material;
g) planarizing the first and second dielectric material such that the insulator is exposed;
h) depositing a laser absorption layer;
i) annealing the gate region such that the first material is not thermally degraded; and
j) removing the laser absorption layer.

19. The method of claim 18 wherein the insulating layer comprises a member of the group consisting of TEOS (give me others).

20. The method of claim 18 wherein the laser absorption layer comprises at least two layers, the first layer an insulating layer and the second layer a conductive layer.

21. The method of claim 20 wherein the second layer, a conductive layer comprises at least about two layers.

22. The method of claim 21 wherein the conductive layer comprises a member selected from the group consisting of tantalum, tantalum nitride, titanium, titanium nitride and combinations thereof.

23. The method of claim 18 wherein the annealing comprises the following steps:
a) a laser anneal; and
b) a rapid thermal anneal.

24. The method of claim 23 wherein the laser anneal is a non-melting laser anneal.

25. The method of claim 10 wherein the anneal is a ultra rapid thermal anneal, the ultra rapid thermal anneal not thermally degrading the high dielectric constant material.
